(19) United States
(12) Patent Application Publication
(10) Pub. No.: US 2024/0312841 A1
(43) Pub. Date: Sep. 19, 2024

(54) ELEMENT CHIP MANUFACTURING METHOD

(71) Applicant: Panasonic Intellectual Property Management Co., Ltd., Osaka (JP)

(72) Inventors: Hidefumi SAEKI, OSAKA (JP); Hidehiko KARASAKI, HYOGO (JP); Shogo OKITA, HYOGO (JP); Toshiyuki TAKASAKI, OSAKA (JP); Akihiro ITOU, KYOTO (JP)

(21) Appl. No.: 18/602,117

(22) Filed: Mar. 12, 2024

(30) Foreign Application Priority Data
Mar. 14, 2023 (JP) 2023-040096

(51) Int. Cl. H01L 21/78; B23K 26/36; H01L 21/56; H01L 21/683

(52) U.S. Cl. CPC H01L 21/78; B23K 26/36; H01L 21/561; H01L 21/568; H01L 21/6836; H01L 2221/68327

(57) ABSTRACT

An element chip manufacturing method disclosed herein includes a preparation process of preparing a substrate having a semiconductor layer, a wiring layer, a plurality of element areas and a dividing area, a resin layer formation process of forming a resin layer covering the wiring layer, an opening formation process of irradiating the wiring layer and the resin layer in the dividing area to form an opening in which the semiconductor layer is exposed in the dividing area, a reflow process of reducing the opening by reflowing the resin layer, and a singulation process of dividing the substrate into a plurality of element chips each including a different one of the element areas, by performing etching of the substrate with plasma along the opening reduced in the reflow process, using the resin layer as a mask.

### CROSS REFERENCE TO RELATED APPLICATION

The present application is based on and claims priority under 35 U.S.C. § 119 with respect to the Japanese Patent Application No. 2023-040096 filed on Mar. 14, 2023, the entire contents of which are incorporated herein by reference into the present application.

### TECHNICAL FIELD

The present disclosure relates to an element chip manufacturing method.

### BACKGROUND

Conventionally, element chip manufacturing methods for obtaining a plurality of element chips by singulating a substrate through plasma etching are known (e.g., JP 2018-6677A). Substrates include a semiconductor layer and a wiring layer formed on the semiconductor layer, and also include a plurality of element areas and a dividing area that defines the element areas, and plasma etching is performed along the dividing area.

However, when a plurality of element chips are obtained through plasma etching, phenomena such as the side surfaces of individual element chips being in a rough state, or edge portions of the wiring layer protruding out further than edge portions of the semiconductor layer may occur. Such phenomena are particularly likely to occur when the Bosch process is applied in the etching. When edge portions of the wiring layer protrude out further than edge portions of the semiconductor layer, separation of the wiring layer can occur starting from the protruding portions. Under such circumstances, one object of the present disclosure is to suppress separation of the wiring layer.

### SUMMARY

One aspect of the present disclosure relates to an element chip manufacturing method. The manufacturing method includes a preparation step of preparing a substrate having a semiconductor layer including a first principal surface and a second principal surface, a wiring layer formed on a first principal surface side of the semiconductor layer, a plurality of element areas, and a dividing area defining the element areas, a resin layer formation step of forming a resin layer covering the wiring layer, an opening formation step of irradiating the resin layer and the wiring layer in the dividing area with a laser beam from the first principal surface side to form an opening in which the semiconductor layer is exposed in the dividing area, a reflow step of reducing the opening by reflowing the resin layer, and a singulation step of dividing the substrate into a plurality of element chips each including a different one of the element areas, by performing etching of the substrate with plasma along the opening reduced in the reflow step, using the resin layer as a mask.

According to the present disclosure, separation of the wiring layer can be suppressed.

### BRIEF DESCRIPTION OF THE DRAWINGS

FIG. 1A is a cross-sectional view showing an example of a substrate held by holding tape.

FIG. 1B is a top view showing an example of a substrate held by holding tape.

FIG. 2A is a cross-sectional view showing a substrate on which a resin layer is formed.

FIG. 2B is a top view showing a substrate on which a resin layer is formed.

FIG. 3A is a cross-sectional view showing a substrate during formation of an opening.

FIG. 3B is a top view showing a substrate during formation of an opening.

FIG. 4A is a cross-sectional view showing a substrate during formation of an opening.

FIG. 4B is a top view showing a substrate during formation of an opening.

FIG. 5A is a cross-sectional view showing a substrate in which an opening is formed.

FIG. 5B is a top view showing a substrate in which an opening is formed.

FIG. 6A is a cross-sectional view showing a substrate after the resin layer is reflowed.

FIG. 6B is a top view showing a substrate after the resin layer is reflowed.

FIG. 7A is a cross-sectional view showing a substrate after debris cleaning.

FIG. 7B is a top view showing a substrate after debris cleaning.

FIG. 8A is a cross-sectional view showing a substrate after singulation.

FIG. 8B is a top view showing a substrate after singulation.

FIG. 9A is a cross-sectional view showing a plurality of element chips obtained by singulating a substrate.

FIG. 9B is a top view showing a plurality of element chips obtained by singulating a substrate.

FIG. 10 is a schematic diagram showing an example of a plasma etching apparatus.

### DETAILED DESCRIPTION

An embodiment of an element chip manufacturing method according to the present disclosure will be described below with reference to examples. However, the present disclosure is not limited to the examples described below. In the following description, specific numerical values and materials are illustrated, but other numerical values and materials may be applied, as long as the effects of the present disclosure are obtained.

The element chip manufacturing method according to the present disclosure is a method for obtaining a plurality of element chips by singulating a substrate through plasma etching. The element chip manufacturing method according to the present disclosure includes a preparation process, a resin layer formation process, an opening formation process, a reflow process, and a singulation process.

In the preparation process, a substrate having a semiconductor layer including a first principal surface and a second principal surface and a wiring layer formed on the first principal surface side of the semiconductor layer is prepared. The substrate has a plurality of element areas and a dividing area that defines the element areas. The semiconductor layer and the wiring layer may be adjacent to each other. A semiconductor material contained in the semiconductor layer is not particularly limited, and may be Si, SiC, GaN, or GaAs, for example. The wiring layer may include an insulating film of SiO₂, SiN, SiCN or the like and metals such as Cu and Al, for example. The element areas are not particularly limited in terms of shape, and may be rectangular, polygonal, or circular, for example. The width of the dividing area is not particularly limited, and can be set as appropriate according to purpose.

In the resin layer formation process, a resin layer that covers the wiring layer is formed. The resin material contained in the resin layer may be water soluble or non-water soluble. The resin layer may contain a resin material having plasma resistance. The resin layer is not particularly limited in terms of thickness, and may be any thickness that does not result in the resin layer being completely removed in the singulation process. A photoresist material, for example, can be illustrated as a non-water-soluble resin material. When a non-water-soluble resin material such as a photoresist material is used, post-baking treatment after application of the resin material is preferably not performed, so as to facilitate flow of the resin layer in the reflow process that is subsequently performed.

In the opening formation process, the resin layer and the wiring layer in the dividing area are irradiated with a laser beam from the first principal surface side to form an opening in which the semiconductor layer is exposed in the dividing area. The laser beam may be an ultrashort pulse laser beam of picosecond order or femtosecond order, but is preferably a short pulse laser beam of nanosecond order from the viewpoint of manufacturing cost. The laser beam is absorbed by the resin layer and the wiring layer, but need not be absorbed by the semiconductor layer. The first principal surface of the semiconductor layer is exposed in the bottom portion of the opening formed in the opening formation process. The exposed width of the semiconductor layer is substantially equal to the distance between opposing portions of the wiring layer across the opening. Note that, due to the irradiation of the laser beam, a certain degree of unevenness occurs on the side surfaces of the wiring layer (or the state of the side surfaces is somewhat rough).

In the reflow process, the opening is reduced by reflowing the resin layer. Reflowing the resin layer involves at least a part of the resin layer being provided with flowability and then resolidified. The means for reflowing the resin layer is not particularly limited, and any means that does not damage the semiconductor layer and the like can be employed. Also, reducing the opening means reducing the width of at least part of the opening, and also includes reducing the width of the entirety of the opening in the depth direction thereof (the entirety from the opening edge to the bottom portion). Due to the reflow process, the exposed width of the semiconductor layer, as viewed from the first principal surface side (as viewed from the opening edge side of the opening), becomes smaller than the distance between opposing portions of the wiring layer across the opening. Furthermore, due to the reflow process, the unevenness of side wall portions of the opening is reduced in the process of the resin layer resolidifying. For example, the edge of the wiring layer scribed with the laser beam is covered with a resin layer that has reflowed from the upper surface, and the roughness of the state of the opening can be ameliorated.

In the singulation process, the substrate is divided into a plurality of element chips each including an element area, by performing etching of the substrate with plasma along the opening reduced in the reflow process, using the resin layer as a mask. As briefly touched on above, the width of the semiconductor layer that is exposed in the bottom portion of the opening, as viewed from the first principal surface side, is smaller than the distance between opposing portions of the wiring layer across the opening. Therefore, the width of the plasma-etched semiconductor layer in a given opening is smaller than the distance between opposing portions of the wiring layer across the opening. Therefore, in the element chips obtained in the singulation process, edge portions of the wiring layer are unlikely to protrude out further than edge portions of the semiconductor layer. In other words, places from which the wiring layer starts separating are unlikely to occur, thus enabling separation of the wiring layer to be suppressed. Also, since the unevenness of side wall portions of the opening is reduced in the reflow process, the unevenness (or line edge roughness) of the side surfaces of the element chips obtained through plasma etching is reduced.

The reflow process may be executed by heating the resin layer. Heating may be performed such that the resin layer reaches a temperature greater than or equal to the melting point of the resin material contained in the resin layer. The resin layer has flowability due to being heated, and, by stopping the heating, the resin layer can resolidify when the temperature thereof decreases.

The reflow process may be executed with the substrate held by holding tape. The resin layer may have a lower melting point than the holding tape. The holding tape may be resin tape having an adhesive layer to which the substrate is adhered. According to this configuration, the resin layer can be reflowed by being heated, while also being able to avoid the holding tape melting due to the heating.

The reflow process may be executed by exposing the resin layer to water vapor. The temperature of the water vapor may be higher than the melting point of the resin material contained in the resin layer. In this case, even if the resin layer contains a non-water-soluble resin material, the resin layer can be reflowed by water vapor. Polyolefin is given as an example of a non-water-soluble resin. On the other hand, the resin material contained in the resin layer may have water solubility. In this case, the resin layer can be reflowed regardless of whether the temperature of the water vapor is higher or lower than the melting point of the resin material. The resin layer may also contain a water-soluble resin. The reflow process may also be executed by exposing the resin layer to atomized water. Alternatively, the reflow process may be executed by exposing the resin layer to water vapor. The water-soluble resin can thereby be provided with flowability by being moistened. The type of water-soluble resin is not particularly limited, and may be a water-soluble polyester, polyvinyl alcohol, or an ethylene oxide polymer, for example.

In the reflow process, the reflowed resin layer may be caused to reach to the side surfaces of the wiring layer in the opening. In other words, there may be a gap between the resolidified resin layer and the bottom portion of the opening (first principal surface of semiconductor layer).

In the reflow process, the reflowed resin layer may be caused to reach to the first principal surface of the semiconductor layer. In other words, the resolidified resin layer may come into contact with the bottom portion of the opening. According to this configuration, it is possible to more accurately protect edge portions of the semiconductor layer from plasma.

As described above, according to the present disclosure, separation of the wiring layer from the semiconductor layer can be suppressed, by reducing the width of the semiconductor layer that is plasma-etched. Furthermore, according to the present disclosure, the unevenness of the side surfaces of the element chips that are obtained can be reduced.

Hereinafter, an example of an element chip manufacturing method according to the present disclosure will be specifically described with reference to the drawings. The above-described processes can be applied as processes of the element chip manufacturing method described below. The example processes of the element chip manufacturing method described below can be changed based on the above description. Also, matters described below may be applied to the above embodiment. Processes that are not essential to the element chip manufacturing method according to the present disclosure, among the example processes of the element chip manufacturing method described below, may be omitted. Note that the diagrams shown below are schematic diagrams, and do not accurately reflect the shapes or numbers of actual members.

The element chip manufacturing method of the present embodiment is a method for obtaining a plurality of element chips by singulating a substrate through plasma etching. The element chip manufacturing method includes a preparation process, a resin layer formation process, an opening formation process, a reflow process, and a singulation process.

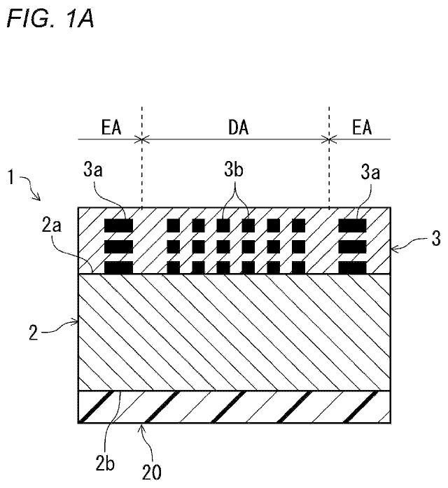

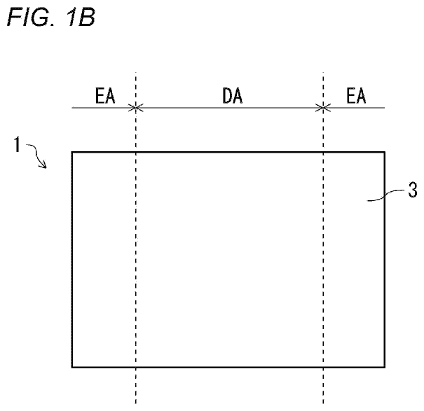

In the preparation process, as shown in FIGS. 1A (cross-sectional view) and 1B (top view), a substrate 1 having a semiconductor layer 2 including a first principal surface 2a and a second principal surface 2b and a wiring layer 3 formed on the first principal surface 2a side of the semiconductor layer 2 (upper side in FIG. 1A) is prepared. The substrate 1 includes a plurality of element areas EA and a dividing area DA defining the element areas EA. The substrate 1 is held from the second principal surface 2b side by holding tape 20 made of resin. At least one metal electrode 3a may be disposed in a portion of the wiring layer 3 that corresponds to each element area EA. Also, at least one metal electrode 3b may be disposed in a portion of the wiring layer 3 that corresponds to the dividing area DA.

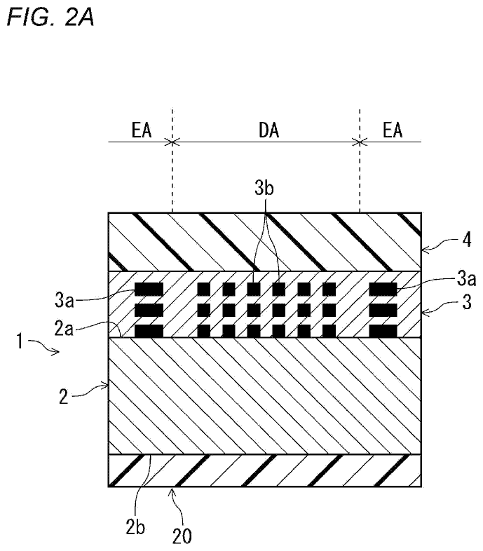

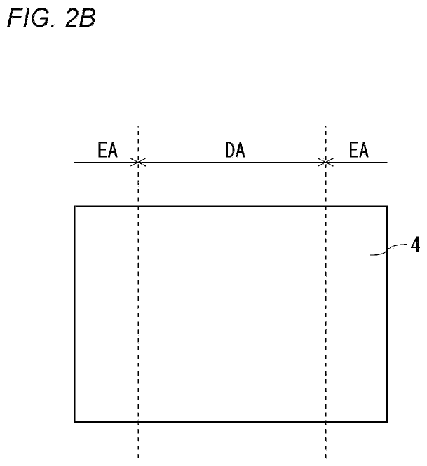

In the resin layer formation process, a resin layer 4 that covers the wiring layer 3 is formed, as shown in FIGS. 2A (cross-sectional view) and 2B (top view). The resin layer 4 contains a water-soluble resin (e.g., water-soluble polyester, polyvinyl alcohol, or ethylene oxide polymer).

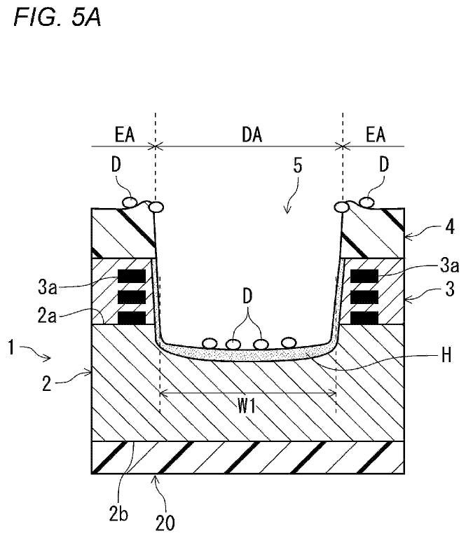

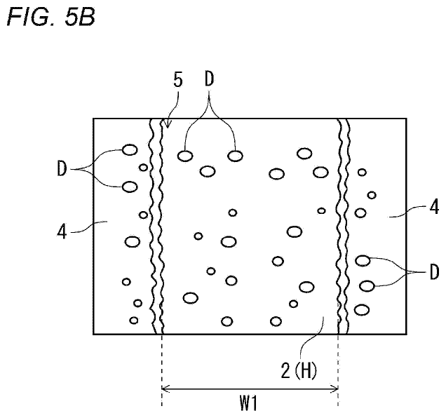

In the opening formation process, the resin layer 4 and the wiring layer 3 in the dividing area DA are irradiated with a laser beam from the first principal surface 2a side to form an opening 5 having a width WI in which the semiconductor layer 2 is exposed in the dividing area DA, as shown in FIGS. 5A (cross-sectional view) and 5B (top view). The semiconductor layer 2 is exposed in the bottom portion of the opening 5 that is formed in the opening formation process. The uppermost surface of the semiconductor layer 2 that is exposed may also be an altered layer H altered under the influence of heat due to being irradiated with the laser beam, or the like. Debris D consisting of components of the substrate 1 and the resin layer 4 removed by the laser beam may also adhere to the surface of the substrate 1. Note that, as shown in FIG. 5B, unevenness may occur on the side surfaces of the opening 5. The laser beam used in the present embodiment is a short pulse laser beam of nanosecond order, but is not limited thereto.

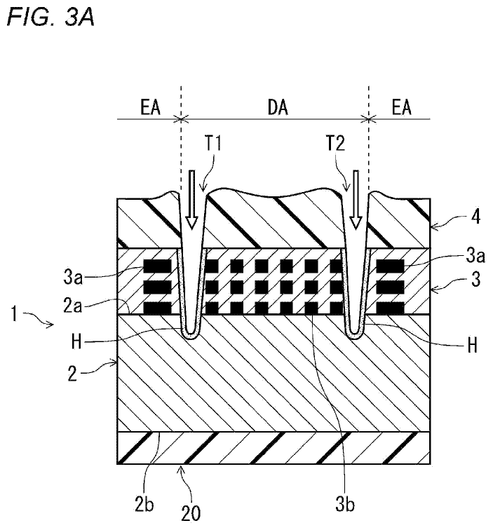

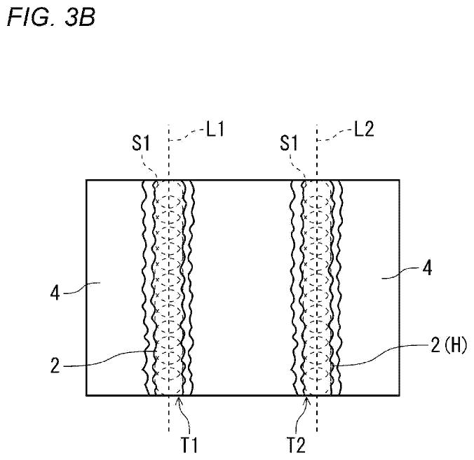

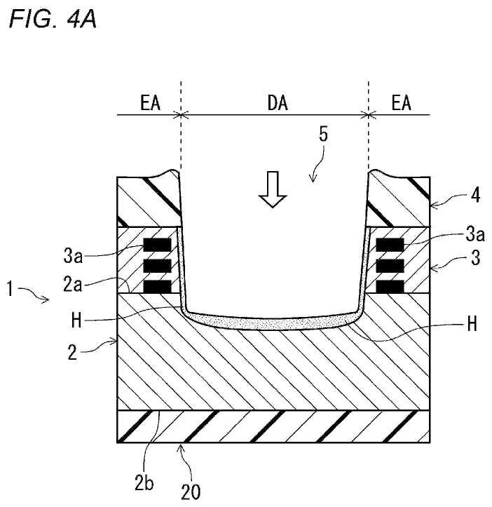

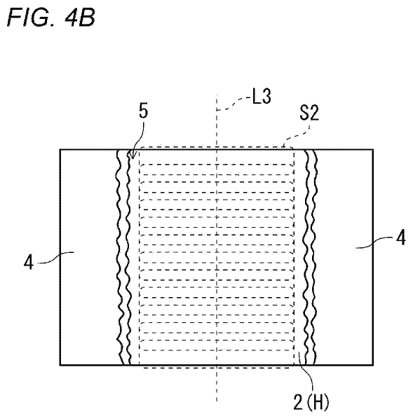

Also, in the opening formation process, the laser beam irradiation may include irradiation of a plurality of laser beams including a first irradiation and a second irradiation. For example, as the first irradiation, as shown in FIGS. 3A (cross-sectional view) and 3B (top view), the resin layer 4 and the wiring layer 3 at both end portions of the dividing area DA near the boundaries between the dividing area DA and the element areas EA are irradiated with a first laser beam from the first principal surface 2a side, and a pair of grooves T1 and T2 in which the semiconductor layer 2 is exposed are formed at both end portions of the dividing area DA. For example, a pulse laser having a circular irradiation spot shape S1 is used as the first laser beam, and this pulse laser is irradiated such that the spots of the laser beam overlap each other along projected irradiation lines L1 and L2 that are set in advance at both end portions of the dividing area DA. The uppermost surface of the semiconductor layer 2 that is exposed by being irradiated with the first laser beam may also be an altered layer H altered under the influence of heat due to irradiation of the laser beam, or the like. Next, as the second irradiation, as shown in FIGS. 4A (cross-sectional view) and 4B (top view), the resin layer 4 and the wiring layer 3 in the area of the dividing area DA sandwiched between the groove T1 and the groove T2 are irradiated with a second laser beam from the first principal surface 2a side to form the opening 5 by removing the resin layer 4 and the wiring layer 3 in the area of the dividing area DA sandwiched between the groove T1 and the groove T2. For example, a pulse laser having a rectangular irradiation spot shape S2 is used as the second laser beam, and the pulse laser is irradiated such that the irradiation spots overlap each other along a projected irradiation line L3 that is set in advance in the area of the dividing area DA sandwiched between the groove T1 and the groove T2. The uppermost surface of the semiconductor layer 2 that is exposed by being irradiated with the second laser beam may also be an altered layer H altered under the influence of heat due to being irradiated with the laser beam, or the like.

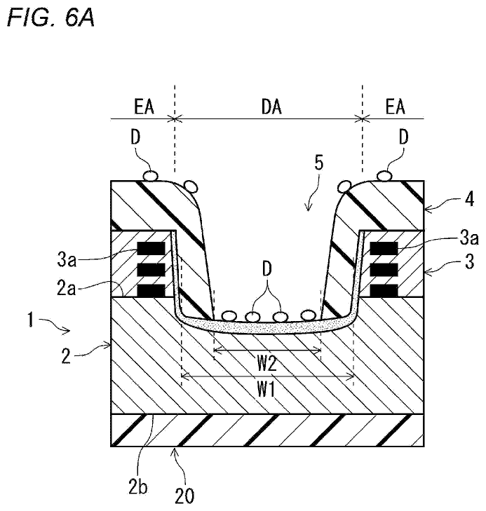

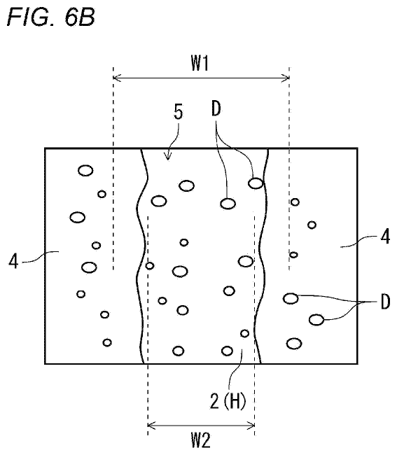

In the reflow process, as shown in FIGS. 6A (cross-sectional view) and 6B (top view), the opening 5 (specifically, the width of the opening 5 in the left-right direction in FIG. 6A) is reduced by reflowing the resin layer 4 with the substrate 1 held by the holding tape 20. The width of the opening 5 thereby becomes W2 (W2<W1). In the present embodiment, the resin layer 4 is reflowed by exposing the resin layer 4 to water vapor, but the present disclosure is not limited thereto. For example, the resin layer 4 may be reflowed by exposing the resin layer 4 to atomized water, or the resin layer 4 may be reflowed by heating the resin layer 4. In the latter case, the resin layer 4 preferably has a lower melting point than the holding tape 20. Note that, as can be seen by comparing FIG. 5B (top view) and FIG. 6B (top view), the unevenness of the side surfaces of the opening 5 formed in the opening formation process are smoothed by the reflow process.

Also, with the reflow process of the present embodiment, the reflowed resin layer 4 is caused to reach to the first principal surface 2a of the semiconductor layer 2 (i.e., to the bottom portion of the opening 5). A configuration may, however, be adopted in which the reflowed resin layer 4 is not caused to reach to the first principal surface 2a. For example, it is conceivable to cause the reflowed resin layer 4 to reach to the side surfaces of the wiring layer 3 in the opening 5.

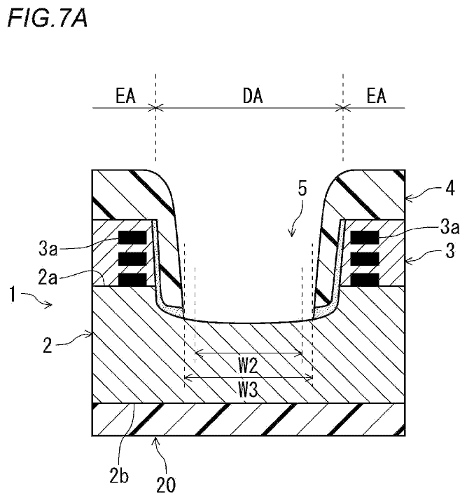

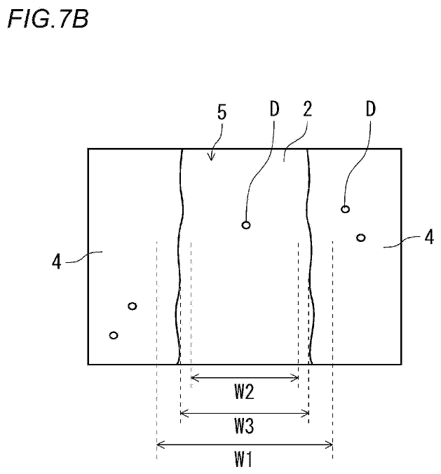

Next, a debris cleaning process is performed. In the debris cleaning process, the amount of debris D adhering to places such as the inner surface of the opening 5 and the upper surface of the resin layer 4 is reduced, as shown in FIGS. 7A (cross-sectional view) and 7B (top view), by exposing the surface of the substrate 1 to plasma containing oxygen and fluorine and etching the surface. Note that, in the debris cleaning process, the resin layer 4 and the altered layer H exposed in the bottom portion of the opening 5 may be etched with plasma. In this case, the width of the opening 5 becomes W3 (W2<W3<W1), and unevenness of the side surfaces of the opening 5 is further smoothed.

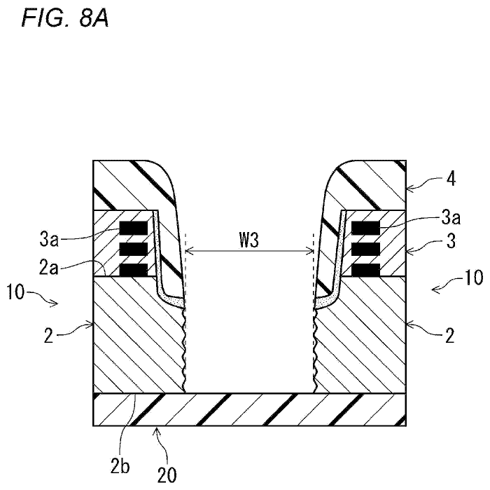

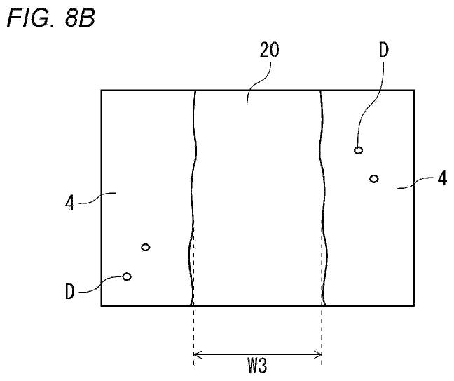

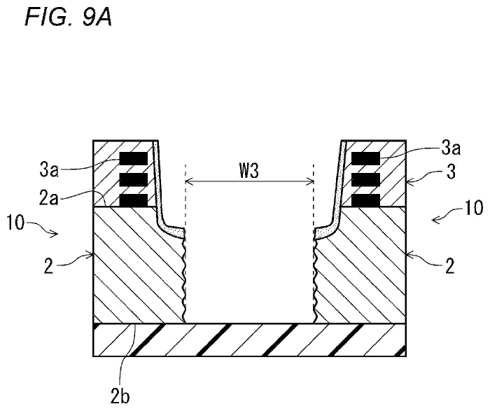

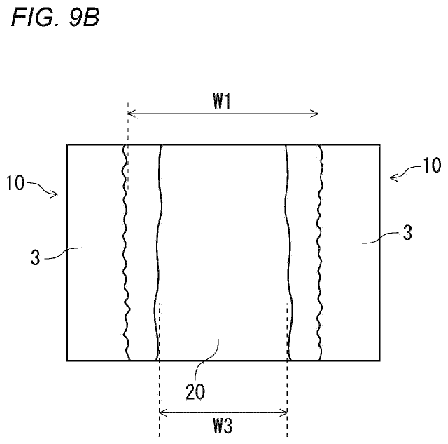

In the singulation process, as shown in FIGS. 8A (cross-sectional view) and 8B (top view), the substrate 1 is divided into a plurality of element chips 10 each including a different one of the element areas EA, by performing etching of the substrate 1 with plasma along the opening 5 reduced in the reflow process, using the resin layer 4 as a mask. Thereafter, as shown in FIGS. 9A (cross-sectional view) and 9B (top view), a resin layer removal process of removing the resin layer 4 is executed. The resin layer removal process may be performed by exposing the resin layer 4 to plasma, or by bringing the resin layer 4 into contact with a liquid that will dissolve the resin layer 4, or by bringing the resin layer 4 into contact with water if the resin layer 4 is water-soluble. In the element chips 10 obtained by the above processes, as can be seen from FIGS. 9A (cross-sectional view) and 9B (top view), edge portions of the wiring layer 3 do not protrude out further than edge portions of the semiconductor layer 2 (or are withdrawn further inward than edge portions of the semiconductor layer 2). Therefore, with the element chips 10 obtained by the element chip manufacturing method of the present embodiment, separation of the wiring layer 3 can be suppressed. In particular, when the substrate 1 is etched using the Bosch process, unevenness called a scallop is formed in the side surfaces of the semiconductor layer 2, and thus edge portions of the wiring layer 3 tend to protrude out slightly. However, according to the present embodiment, by performing the reflow process, edge portions of the wiring layer 3 are unlikely to protrude out, and separation of the wiring layer 3 can be suppressed. Also, according to the present embodiment, unevenness of the side surfaces of the clement chips 10 can be smoothed compared to when the reflow process is not performed, and the flexural strength of the element chips 10 improves.

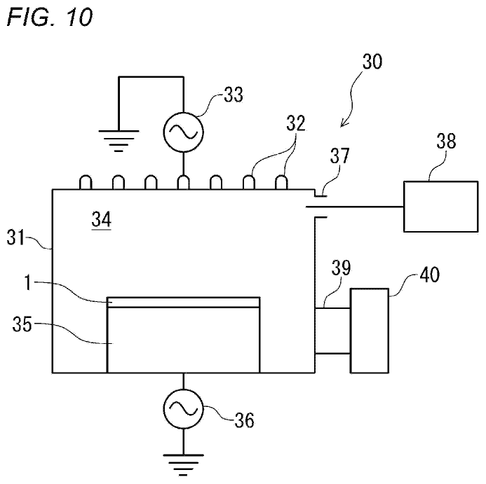

In the singulation process, the debris cleaning process, and the resin layer removal process, a plasma etching apparatus 30 shown in FIG. 10 may be used. The plasma etching apparatus 30 includes a chamber 31 that is provided with a dielectric window in a top portion and defines a treatment chamber 34, an antenna 32 serving as an upper electrode that is provided on the upper side of the chamber 31, a first high-frequency power source 33 that is electrically connected to the antenna 32, a stage 35 serving as a lower electrode on which the substrate 1 is placed and that is provided on the bottom portion side of the treatment chamber 34, and a second high-frequency power source 36 that is electrically connected to the stage 35. A gas inlet 37 provided in the chamber 31 is fluidly connected to an etching gas source 38. An exhaust port 39 provided in the chamber 31 is fluidly connected to an evacuation unit 40 that includes a vacuum pump.

With the plasma etching apparatus 30 shown in FIG. 10, after placing the substrate 1 on the stage 35, the treatment chamber 34 is depressurized by the evacuation unit 40, and etching gas is supplied to the treatment chamber 34 from the etching gas source 38. Thereafter, high-frequency power is supplied to the antenna 32 from the first high-frequency power source 33, plasma is generated in the treatment chamber 34, and the substrate 1 is irradiated with the plasma. Due to the physicochemical action of radicals and ions in the plasma, the semiconductor layer 2 exposed in the opening 5 can be removed. Note that by supplying high-frequency power to the stage 35 from the second high-frequency power source 36, it is possible to control the collision rate of radicals and ions with the substrate 1.

Although preferred embodiments of the present disclosure have been described, the scope of the present disclosure should not be construed as being limited by this description. For example, as long as no technical inconsistences arise, matters described in two or more of the claims freely selected from the appended claims can be combined.

### Supplementary Notes

The following techniques are disclosed by the above description of the embodiment.

### Technique 1

An element chip manufacturing method including:
a preparation step of preparing a substrate having a semiconductor layer including a first principal surface and a second principal surface, a wiring layer formed on a first principal surface side of the semiconductor layer, a plurality of element areas, and a dividing area defining the element areas;
a resin layer formation step of forming a resin layer covering the wiring layer;
an opening formation step of irradiating the resin layer and the wiring layer in the dividing area with a laser beam from the first principal surface side to form an opening in which the semiconductor layer is exposed in the dividing area;
a reflow step of reducing the opening by reflowing the resin layer; and
a singulation step of dividing the substrate into a plurality of element chips each including a different one of the element areas, by performing etching of the substrate with plasma along the opening reduced in the reflow step, using the resin layer as a mask.

### Technique 2

The element chip manufacturing method according to technique 1, wherein the reflow step is executed by heating the resin layer.

### Technique 3

The element chip manufacturing method according to technique 2, wherein the reflow step is executed with the substrate held by holding tape, and the resin layer has a lower melting point than the holding tape.

### Technique 4

The element chip manufacturing method according to technique 1, wherein the reflow step is executed by exposing the resin layer to water vapor.

### Technique 5

The element chip manufacturing method according to technique 4, wherein the resin layer contains a water-soluble resin.

### Technique 6

The element chip manufacturing method according to any one of techniques 1 to 5, wherein, in the reflow step, the reflowed resin layer is caused to reach to a side surface of the wiring layer in the opening.

### Technique 7

The element chip manufacturing method according to any one of techniques 1 to 5, wherein, in the reflow step, the reflowed resin layer is caused to reach to the first principal surface of the semiconductor layer.

The present disclosure can be utilized in element chip manufacturing methods.

### Reference Numerals

1: Substrate
2: Semiconductor layer
2a: First principal surface
2b: Second principal surface
3: Wiring layer
3a: Metal electrode
3b: Metal electrode
4: Resin layer
5: Opening
10: Element chip
20: Holding tape
30: Plasma etching apparatus
31: Chamber
32: Antenna
33: First high-frequency power source
34: Treatment room
35: Stage
36: Second high-frequency power source
37: Gas inlet
38: Etching gas source
39: Exhaust port
40: Evacuation unit
EA: Element area
DA: Dividing area
D: Debris
H: Altered layer
L1, L2, L3: Projected irradiation line
S1, S2: Irradiation spot shape
T1, T2: Groove
W1, W2, W3: Width of opening

What is claimed is:

1. An element chip manufacturing method comprising:
a preparation step of preparing a substrate having a semiconductor layer including a first principal surface and a second principal surface, a wiring layer formed on a first principal surface side of the semiconductor layer, a plurality of element areas, and a dividing area defining the element areas;
a resin layer formation step of forming a resin layer covering the wiring layer;
an opening formation step of irradiating the resin layer and the wiring layer in the dividing area with a laser beam from the first principal surface side to form an opening in which the semiconductor layer is exposed in the dividing area;
a reflow step of reducing the opening by reflowing the resin layer; and
a singulation step of dividing the substrate into a plurality of element chips each including a different one of the element areas, by performing etching of the substrate with plasma along the opening reduced in the reflow step, using the resin layer as a mask.

2. The element chip manufacturing method according to claim 1,
wherein the reflow step is executed by heating the resin layer.

3. The element chip manufacturing method according to claim 2,
wherein the reflow step is executed with the substrate held by holding tape, and
the resin layer has a lower melting point than the holding tape.

4. The element chip manufacturing method according to claim 1,
wherein the reflow step is executed by exposing the resin layer to water vapor.

5. The element chip manufacturing method according to claim 4,
wherein the resin layer contains a water-soluble resin.

6. The element chip manufacturing method according to claim 1,
wherein, in the reflow step, the reflowed resin layer is caused to reach to a side surface of the wiring layer in the opening.

7. The clement chip manufacturing method according to claim 1.
wherein, in the reflow step. the reflowed resin layer is caused to reach to the first principal surface of the semiconductor layer.
